(19) United States
(12) Patent Application Publication
(10) Pub. No.: US 2018/0213650 A1
(43) Pub. Date: Jul. 26, 2018

(54) MANUFACTURING METHODS OF FLEXIBLE SUBSTRATES AND FLEXIBLE PANELS BY SCREEN PRINTING MACHINES

(71) Applicant: Wuhan China Star Optoelectronics Technology Co., Ltd., Wuhan, Hubei (CN)

(72) Inventors: Xiang LI, Shenzhen, Guangdong (CN); Wei YU, Shenzhen, Guangdong (CN)

(73) Assignee: Wuhan China Star Optoelectronics Technology Co., Ltd., Wuhan, Hubei (CN)

(21) Appl. No.: 15/327,796

(22) PCT Filed: Jan. 13, 2017
(86) PCT No.: PCT/CN2017/071070

§ 371 Date: Jan. 20, 2017

(30) Foreign Application Priority Data
Dec. 23, 2016 (CN) 2016112074819

(51) Int. Cl. H05K 3/12; H05K 1/02; H01L 51/00; H05K 3/22; H05K 3/38

(52) U.S. Cl. CPC H05K 3/1216; H05K 1/028; H01L 2227/326; H05K 3/227; H05K 3/381; H01L 51/0097

(57) ABSTRACT

A manufacturing method of flexible substrates via a screen printing machine includes moving the back-ink blade and the scraper, the scraper is above the back-ink blade, and the back-ink blade is configured to coat the adhesive material on the opening; moving the back-ink blade and the scraper along an opposite direction, the scraper is lowered down to a position below the back-ink blade, the scraper prints the adhesive material from the opening to the substrate so as to form a flexible substrate thin-film corresponding to the opening area on the substrate; and applying a baking process on the flexible substrate thin-film to obtain a cured flexible substrate. The screen printing machine forms the flexible substrate thin-film corresponding to the opening of the screen printing machine to so as to obtain the flexible substrate having a predetermined dimension, which simplifies the manufacturing process and saves the manufacturing cost.

### BACKGROUND OF THE INVENTION

### 1. Field of the Invention

The present disclosure relates to display technology, and more particularly to a manufacturing method of flexible substrates and flexible panels by a screen printing machine.

### 2. Discussion of the Related Art

Organic light emitting diodes (OLEDs) are characterized by attributes, such as self-light-emitting, wide viewing angle, high contrast, low power consumption, and quick response time. Thus, the OLEDs have been widely adopted in the display technology, and also our normal life.

With the rapid development of OLEDs, regardless of the dimension of the panels or the display performance, the flexible and transformable devices have been greatly enhanced. The main manufacturing method of OLED component relates to coating Polyimide on a whole surface of the glass substrate to form a flexible substrate, and the electronic components, and the optical components are packaged on the flexible substrate. Afterward, a laser cutting machine is adopted to cutting the glass substrate and the flexible substrate to be the panels. In the end, the laser stripping machine (LLO) is adopted to stripe the flexible OLED components from the glass substrate so as to form the flexible OLED components. The coating cost of the above manufacturing process is high, and the manufacturing process is very complicated. In addition, the cost of adopting the laser cutting machine is also pretty high, which increases the manufacturing cost.

### SUMMARY

The present disclosure relates to a manufacturing method of flexible substrates and flexible panels by a screen printing machine, which resolves the above-mentioned issues of the conventional manufacturing process of flexible OLED components.

In one aspect, a manufacturing method of flexible substrates via a screen printing machine, the screen printing machine comprises a stencil having at least one opening, a back-ink blade above the stencil, a scraper, and adhesive material, a bottom side of the stencil is configured with a substrate arranged; the manufacturing method includes moving the back-ink blade and the scraper, the scraper is above the back-ink blade, and the back-ink blade is configured to coat the adhesive material on the opening; moving the back-ink blade and the scraper along an opposite direction, the scraper is lowered down to a position below the back-ink blade, the scraper prints the adhesive material from the opening to the substrate so as to form a flexible substrate thin-film corresponding to the opening area on the substrate; and applying a baking process on the flexible substrate thin-film to obtain a cured flexible substrate, wherein a temperature of the baking process is in a range from 350 to 500 Celsius degrees, a time period of the backing process is in a range from 2 to 4 hours, and a thickness of the flexible substrate is in a range from 20 to 400 micrometers.

In one aspect, a manufacturing method of flexible substrates via a screen printing machine , the screen printing machine comprises a stencil having at least one opening, a back-ink blade above the stencil, a scraper, and adhesive material, a bottom side of the stencil is configured with a substrate arranged; moving the back-ink blade and the scraper, the scraper is above the back-ink blade, and the back-ink blade is configured to coat the adhesive material on the opening; the manufacturing method includes moving the back-ink blade and the scraper along an opposite direction, the scraper is lowered down to a position below the back-ink blade, the scraper prints the adhesive material from the opening to the substrate so as to form a flexible substrate thin-film corresponding to the opening area on the substrate; and applying a baking process on the flexible substrate thin-film to obtain a cured flexible substrate.

Wherein a temperature of the baking process is in a range from 350 to 500 Celsius degrees, and a time period of the backing process is in a range from 2 to 4 hours.

Wherein the temperature of the baking process is in a range from 400 to 450 Celsius degrees, and the time period of the backing process is in a range from 2.5 to 3.5 hours.

Wherein the adhesive material is one of polyethylene (PE), polypropylene (PP), polystyrene (PS), polyethylene terephthalate (PET), polyethylene naphthalate (PEN (PM)) and polyimide (PI).

Wherein the adhesive material is the PI.

Wherein a thickness of the flexible substrate is in a range from 20 to 400 micrometers.

Wherein the thickness of the flexible substrate is in a range from 50 to 100 micrometers.

Wherein a dimension of the opening area is in a range from 6 to 10000 centimeters.

Wherein a gap between the two adjacent opening areas is in a range from 5 to 100 millimeters.

In another aspect, a manufacturing method of flexible substrates via a screen printing machine includes: manufacturing a flexible substrate by the above method; arranging a thin film transistor (TFT), a lighting component, and a package thin film on the flexible substrate in sequence; and stripping the flexible substrate and the substrate via a laser stripping process.

Wherein a temperature of the baking process is in a range from 350 to 500 Celsius degrees, and a time period of the backing process is in a range from 2 to 4 hours.

Wherein the temperature of the baking process is in a range from 400 to 450 Celsius degrees, and the time period of the backing process is in a range from 2.5 to 3.5 hours.

Wherein the adhesive material is one of polyethylene (PE), polypropylene (PP), polystyrene (PS), polyethylene terephthalate (PET), polyethylene naphthalate (PEN (PM)) and polyimide (PI).

Wherein the adhesive material is the PI.

Wherein a thickness of the flexible substrate is in a range from 20 to 400 micrometers.

Wherein the thickness of the flexible substrate is in a range from 50 to 100 micrometers.

Wherein a dimension of the opening area is in a range from 6 to 10000 centimeters.

Wherein a gap between the two adjacent opening areas is in a range from 5 to 100 millimeters.

In view of the above, the screen printing machine forms the flexible substrate thin-film corresponding to the opening of the screen printing machine to so as to obtain the flexible substrate having a predetermined dimension, which simplifies the manufacturing process and saves the manufacturing cost.

### BRIEF DESCRIPTION OF THE DRAWINGS

Embodiments of the invention will now be described more fully hereinafter with reference to the accompanying drawings, in which embodiments of the invention are shown. Apparently, the accompanying drawings are only some embodiments of the claimed invention. Those of ordinary skill can derive other drawings from these drawings without creative efforts.

FIG. 1 is a flowchart illustrating the manufacturing method of flexible substrates via a screen printing machine in accordance with one embodiment of the present invention.

FIG. 2 is a schematic view of the screen printing machine in accordance with one embodiment of the present invention.

FIG. 2a is a schematic view showing the structure when the screen printing machine is moved along a first direction in accordance with one embodiment of FIG. 2.

FIG. 2b is a schematic view showing the structure when the screen printing machine is moved along a second direction opposite to the first direction in accordance with one embodiment of FIG. 2a.

FIG. 3 is a schematic view of the flexible substrate in accordance with one embodiment of the present invention.

FIG. 4 is a flowchart illustrating the manufacturing method of flexible panel via the screen printing machine in accordance with one embodiment of the present invention.

FIG. 5 is a schematic view of the flexible panel in accordance with one embodiment.

### DETAILED DESCRIPTION OF THE EMBODIMENTS

Embodiments of the invention will now be described more fully hereinafter with reference to the accompanying drawings, in which embodiments of the invention are shown.

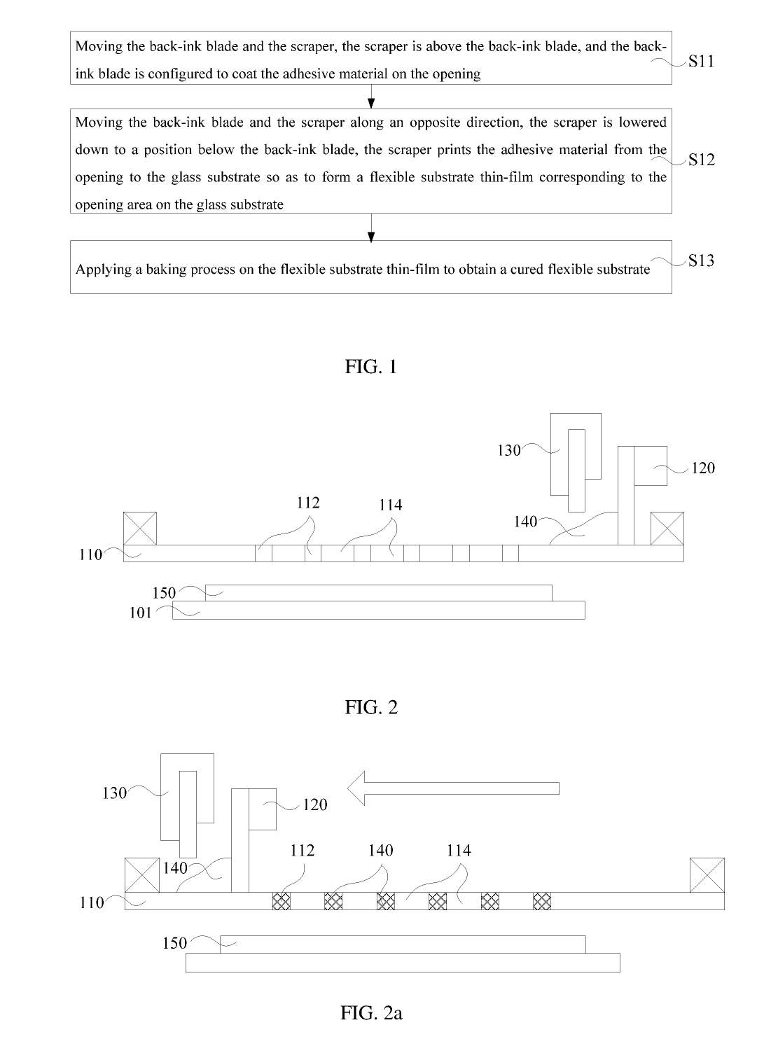

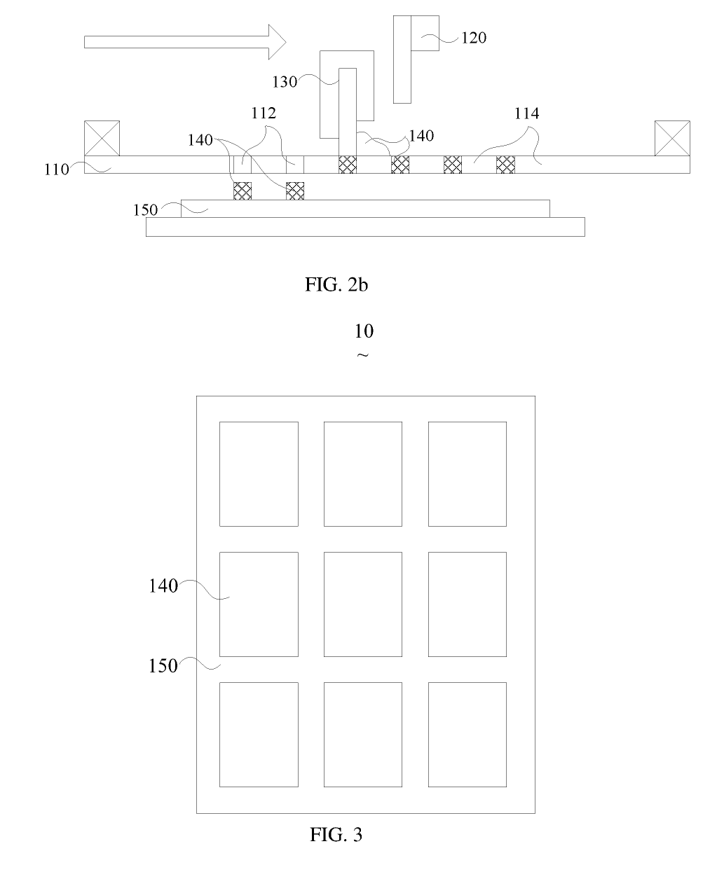

FIG. 1 is a flowchart illustrating the manufacturing method of flexible substrates via a screen printing machine in accordance with one embodiment. FIGS. 2, 2a, and 2b are schematic views of the screen printing machine.

As shown in FIG. 2, the screen printing machine 100 includes a stencil 110 having at least one opening 112, a back-ink blade 120 above the stencil, a scraper 130, and adhesive material 140. A bottom side of the stencil 110 is configured with a substrate 150 arranged on a carrying table 101.

The screen printing machine adopts screen printing technology, and is one of the printing machine. The screen printing machine has good adapting ability toward the material and the shape of the substrates, and also toward large-scale substrates. The screen printing machine may print texts or images, and is a collected term with respect to the devices or machines for generating the prints. The screen printing machine is one of the represented printing machine among the stencil printing machines. In addition to silk, the screen printing machine may also print the Nylon wire, copper wire, steel wire, and stainless steel wire. Further, the screen printing machine may further include flat screen printing machine, curved screen printing machine, rotary screen printing machine, and so on. In the present embodiment, the screen printing machine adopts stainless steel wire plane.

FIG. 1 is a flowchart illustrating the manufacturing method of flexible substrates via a screen printing machine in accordance with one embodiment. The method includes the following steps.

In step S11, moving the back-ink blade 120 and the scraper 130, the scraper 130 is above the back-ink blade 120, and the back-ink blade 120 is configured to coat adhesive material on the opening 112.

As shown in FIG. 2a, when the back-ink blade 120 and the scraper 130 are moved from right to left/along a first direction, the scraper 130 is above the back-ink blade 120, and the back-ink blade 120 coats the adhesive material 140 in a lateral side of the back-ink blade 120 on the opening 112.

The stencil 110 of the screen printing machine 100 includes an opening area 112 and a closed area 114. The opening area 112 and the closed area 114 are spaced apart and are configured as a stencil having a flat surface. The dimension of the stencil is in a range from 300*300 mm to 2000*3000 mm Further, the dimension of the stencil is in a range from 650*650 mm to 1000*1000 mm In addition, the dimension of the stencil 110 is greater than the dimension of the substrate 150. The closed area 114 is configured to print photo-sensitive paste on the corresponding stencil. The photo-sensitive paste is cross-linked and cured by the action of a sensitizer under the irradiation of ultraviolet rays to close the closed region 114. The opening area 112 has not been printed with the photo-sensitive paste, and swollen and dissolved when contacting with water. After being developed, a predetermined pattern the same with the flexible substrate may be obtained.

The adhesive material 140 may be one of polyethylene (PE), polypropylene (PP), polystyrene (PS), polyethylene terephthalate (PET), polyethylene naphthalate (PEN (PM)) and polyimide (PI). Among the above materials, polyimide (PI) is one of the most excellent organic polymer materials with high temperature resistance up to 400 Celsius degrees, and a long-term-use temperature may be in a range from −200 to 300 Celsius degrees. In addition, the PI is also characterized by attributes such as no obvious melting point, with excellent mechanical properties, high insulation properties, and thus is the most commonly used material for flexible substrates.

In step S12, moving the back-ink blade 120 and the scraper 130 along a second direction opposite to the first direction. The scraper 130 is lowered down to a position below the back-ink blade 120. The scraper 130 prints the adhesive material from the opening to the substrate 150 so as to form a flexible substrate thin-film corresponding to the opening area 112 on the substrate.

As shown in FIG. 2b, when the back-ink blade 120 and the scraper 130 are moved along the second direction, i.e., from left to right, the scraper 130 is lowered down to the position below the back-ink blade 120. This generates a pressure to the stencil to a certain degree. The scraper 130 prints the adhesive material 140 from the opening area 112 to the substrate 150 so as to form the flexible substrate thin-film corresponding to the opening area 112 on the substrate 150.

In step S13, applying a baking process on the flexible substrate thin-film to obtain a cured flexible substrate.

In view of the above, the screen printing machine forms the flexible substrate thin-film corresponding to the opening of the screen printing machine to so as to obtain the flexible substrate having a predetermined dimension, which simplifies the manufacturing process and saves the manufacturing cost.

Specifically, a temperature of the baking process is in a range from 350 to 500 Celsius degrees, and a time period of the backing process is in a range from 2 to 4 hours. In addition, the temperature of the baking process is in a range from 400 to 450 Celsius degrees, and the time period of the backing process is in a range from 2.5 to 3.5 hours. After the baking process, the thickness of the flexible substrate is in a range from 20 to 400 micrometers. Further, after the baking process, the thickness of the flexible substrate is in a range from 50 to 100 micrometers

A dimension of the opening area 112 is in a range from 6 to 10000 centimeters. Further, the dimension of the opening area 112 is in a range from 50 to 2500 centimeters. Further, when the dimension of the opening area 112 is 100 centimeters and when the shape of the opening area 112 is a rectangle or a square, a length or a width of the rectangle or the square is in range from 1 to 50 inch. Preferably, the length or the width of the rectangle or the square is in range from 4 to 10 inches. Preferably, the length or the width of the rectangle or the square is 6 inches, wherein a gap between the two adjacent opening areas 112 is in a range from 5 to 100 millimeters. Preferably, the gap between the two adjacent opening areas 112 in a range from 10 to 40 millimeters. Preferably, the gap between the two adjacent opening areas 112 in 30 millimeters.

FIG. 3 is a schematic view of the flexible substrate in accordance with one embodiment.

As shown in FIG. 3, the flexible substrate 10 is made by the above method. The flexible substrate 10 includes a substrate 150 and a flexible substrate 140, wherein the flexible substrate 140 is patterned on the substrate 150. The manufacturing method of the flexible substrate 140 are described in the above, and thus are omitted hereinafter.

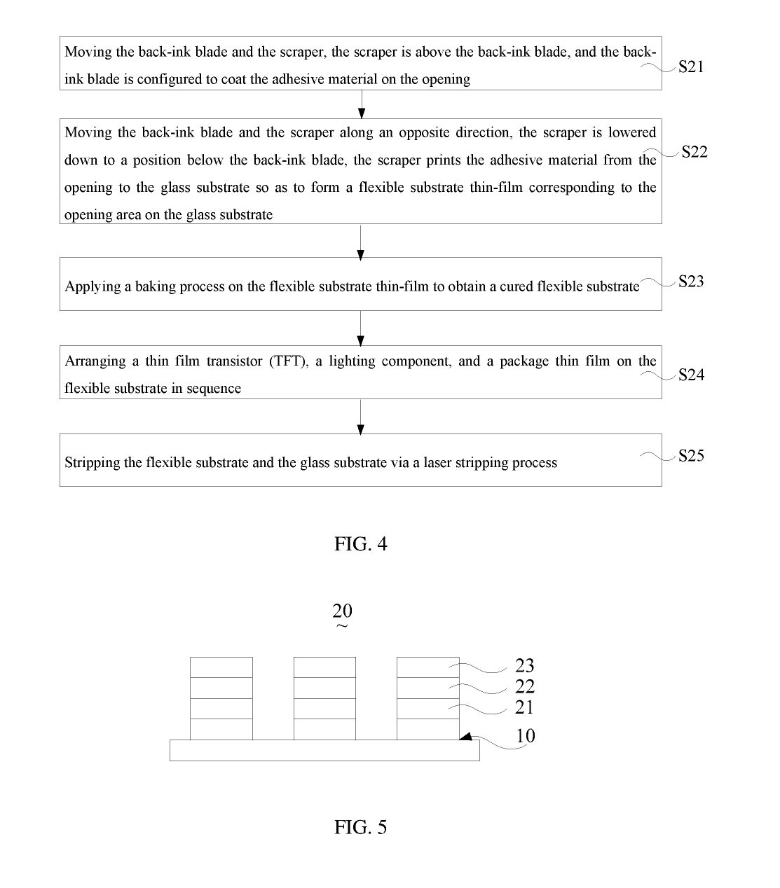

FIG. 4 is a flowchart illustrating the manufacturing method of flexible panels via the screen printing machine in accordance with one embodiment. The method includes the following steps.

The steps S21-S23 are substantially similar to the steps S11-S13. In the embodiment, the electronic components and the lighting components are arranged on the flexible substrate, which are described in steps S24 and S25.

In step S24, a thin film transistor (TFT), a lighting component, and a package thin film are arranged on the flexible substrate in sequence.

The step S24 is similar to the conventional process of forming the TFT, the lighting component, and the package thin film, and thus the descriptions thereof are omitted hereinafter.

In step S25, adopting a laser stripping process to strip the flexible substrate from the substrate.

In view of the above, the screen printing machine forms the flexible substrate thin-film corresponding to the opening of the screen printing machine. In addition, the TFT, the lighting component, and the package thin film are arranged on the flexible substrate. As such, the step of cutting the whole glass together with the flexible substrate by a laser cutting machine may be omitted. Thus, the manufacturing process is simplified, and the manufacturing cost is reduced.

FIG. 5 is a schematic view of the flexible panel in accordance with one embodiment.

The flexible panel 20 is formed by the above method. The flexible substrate 20 includes a flexible substrate 10 and a TFT 21, a lighting component 22, and a package thin film 23, wherein the flexible substrate 10 may be made by the above manufacturing method.

In view of the above, the screen printing machine forms the flexible substrate thin-film corresponding to the opening of the screen printing machine to so as to obtain the flexible substrate having a predetermined dimension, which simplifies the manufacturing process and saves the manufacturing cost.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of flexible substrates via a screen printing machine, the screen printing machine comprising a stencil having at least one opening, a back-ink blade above the stencil, a scraper, and adhesive material, a bottom side of the stencil being configured with a substrate arranged, the manufacturing method comprising:
moving the back-ink blade and the scraper along a first direction, the scraper being arranged above the back-ink blade, and the back-ink blade being configured to coat the adhesive material on the opening;
moving the back-ink blade and the scraper along a second direction opposite to the first direction, the scraper being lowered down to a position below the back-ink blade, the scraper printing the adhesive material from the opening to the substrate so as to form a flexible substrate thin-film corresponding to the opening area on the substrate; and
applying a baking process on the flexible substrate thin-film to obtain a cured flexible substrate, wherein a temperature of the baking process is in a range from 350 to 500 Celsius degrees, a time period of the backing process is in a range from 2 to 4 hours, and a thickness of the flexible substrate is in a range from 20 to 400 micrometers.

2. A manufacturing method of at least one flexible substrate via a screen printing machine, the screen printing machine comprising a stencil having at least one opening, a back-ink blade above the stencil, a scraper, and adhesive material, a bottom side of the stencil being configured with a substrate arranged; the manufacturing method comprising:
moving the back-ink blade and the scraper along a first direction, the scraper being above the back-ink blade, and the back-ink blade being configured to coat the adhesive material on the opening;
moving the back-ink blade and the scraper along a second direction opposite to the first direction, the scraper being lowered down to a position below the back-ink blade, the scraper printing the adhesive material from the opening to the substrate so as to form a flexible substrate thin-film corresponding to the opening area on the substrate; and
applying a baking process on the flexible substrate thin-film to obtain a cured flexible substrate.

3. The manufacturing method as claimed in claim 2, wherein a temperature of the baking process is in a range from 350 to 500 Celsius degrees, and a time period of the backing process is in a range from 2 to 4 hours.

4. The manufacturing method as claimed in claim 3, wherein the temperature of the baking process is in a range from 400 to 450 Celsius degrees, and the time period of the backing process is in a range from 2.5 to 3.5 hours.

5. The manufacturing method as claimed in claim 2, wherein the adhesive material is one of polyethylene (PE), polypropylene (PP), polystyrene (PS), polyethylene terephthalate (PET), polyethylene naphthalate (PEN (PM)) and polyimide (PI).

6. The manufacturing method as claimed in claim 5, wherein the adhesive material is the PI.

7. The manufacturing method as claimed in claim 2, wherein a thickness of the flexible substrate is in a range from 20 to 400 micrometers.

8. The manufacturing method as claimed in claim 7, wherein the thickness of the flexible substrate is in a range from 50 to 100 micrometers.

9. The manufacturing method as claimed in claim 2, wherein a dimension of the opening area is in a range from 6 to 10000 centimeters.

10. The manufacturing method as claimed in claim 2, wherein a gap between the two adjacent opening areas is in a range from 5 to 100 millimeters.

11. A manufacturing method of at least one flexible panel via a screen printing machine, comprising:
manufacturing at least one flexible substrate by the method as claimed in claim 2;
arranging a thin film transistor (TFT), a lighting component, and a package thin film on the flexible substrate in sequence; and
stripping the flexible substrate from the substrate.

12. The manufacturing method as claimed in claim 11, wherein a temperature of the baking process is in a range from 350 to 500 Celsius degrees, and a time period of the backing process is in a range from 2 to 4 hours.

13. The manufacturing method as claimed in claim 12, wherein the temperature of the baking process is in a range from 400 to 450 Celsius degrees, and the time period of the backing process is in a range from 2.5 to 3.5 hours.

14. The manufacturing method as claimed in claim 11, wherein the adhesive material is one of polyethylene (PE), polypropylene (PP), polystyrene (PS), polyethylene terephthalate (PET), polyethylene naphthalate (PEN (PM)) and polyimide (PI).

15. The manufacturing method as claimed in claim 14, wherein the adhesive material is the PI.

16. The manufacturing method as claimed in claim 14, wherein a thickness of the flexible substrate is in a range from 20 to 400 micrometers.

17. The manufacturing method as claimed in claim 16, wherein the thickness of the flexible substrate is in a range from 50 to 100 micrometers.

18. The manufacturing method as claimed in claim 11, wherein a dimension of the opening area is in a range from 6 to 10000 centimeters.

19. The manufacturing method as claimed in claim 11, wherein a gap between the two adjacent opening areas is in a range from 5 to 100 millimeters.
